(19) United States
(12) Patent Application Publication
(10) Pub. No.: US 2009/0315120 A1
(43) Pub. Date: Dec. 24, 2009

(54) RAISED FACET- AND NON-FACET 3D SOURCE/DRAIN CONTACTS IN MOSFETS

(76) Inventors: Lucian Shifren, Hillsboro, OR (US); Keith Zawadzki, Portland, OR (US); Martin Giles, Portland, OR (US); Cory Weber, Hillsboro, OR (US)

Correspondence Address: CENTURY IP GROUP, INC. [Intel], C/O CPA GLOBAL, P.O BOX 52050, MINNEAPOLIS, MN, 55402, US

(21) Appl. No.: 12/145,296

(22) Filed: Jun. 24, 2008

(51) Int. Cl. H01L 29/78; H01L 21/336

(52) U.S. Cl. 257/386; 438/300; 257/E29.255; 257/E21.424

(57) ABSTRACT

An apparatus comprising a semiconductor substrate; a conductively doped source or drain (source/drain) region at the surface of the substrate; a raised semiconductor layer deposited over the source/drain region to form a raised source/drain region; a via formed in the raised source/drain region having substantially vertical sidewalls reaching partly or substantially to the source/drain region; and a metal contact filling the via.

### BACKGROUND

The present invention relates generally to semiconductor devices, and more particularly to reducing parasitic resistance in source and drain contacts in integrated circuit transistors.

Source and drain contact resistance in a semiconductor device is proportional to the size of the contact area. In complementary metal-oxide-semiconductor (CMOS) devices, as the length of a device gate decrease, the contact resistance of the CMOS device becomes a more dominant source of resistance. As total device size decreases, the contact are also decreases rapidly. Hence, resistive heat dissipation may be the largest source of degradation in CMOS design and scaling in to smaller sizes. In addition, gate scaling causes worsening short channel effects, which causes the threshold voltage to operate the transistor to increase undesirably.

### BRIEF DESCRIPTION OF THE DRAWINGS

Embodiments of the present invention are understood by referring to the figures in the attached drawings, as provided below.

FIG. 1A shows a cross section of a source/drain region in a NMOS MOSFET device, in accordance with one embodiment.

FIG. 1B shows a cross section of a NMOS MOSFET device, illustrating a source/drain region having a raised contact, in accordance with one embodiment

FIGS. 2A-2E illustrate various steps in forming an improved contact in a non-faceted raised source/drain region according to one embodiment.

FIGS. 3A-3D illustrate various steps in forming an improved contact in a non-faceted raised source/drain region according to another embodiment.

FIGS. 4A-4D illustrate various steps in forming an improved contact in a faceted raised source/drain region according to another embodiment.

Features, elements, and aspects of the invention that are referenced by the same numerals in different figures represent the same, equivalent, or similar features, elements, or aspects, in accordance with one or more embodiments.

### DETAILED DESCRIPTION OF EXEMPLARY EMBODIMENTS

In the following, numerous specific details may be set forth, such as specific dimensions and chemical regimes, in order to provide a thorough understanding of the present invention. It will be apparent to one skilled in the art that the present invention may be practiced without these specific details. In other instances, well-known processing steps, such as patterning steps or wet chemical cleans, may not be described in detail to avoid unnecessarily obscuring the present invention. Furthermore, it is should be understood that the various embodiments shown in the figures are illustrative representations and are not necessarily drawn to scale. It is also noteworthy that the processes, methods, and the order in which the respective elements of each method are performed are purely exemplary. Depending on the implementation, they may be performed in a different order or in parallel, unless indicated otherwise in the present disclosure.

In one embodiment, a raised source/drain contact in a MOSFET includes a semiconductor substrate; a conductively doped source or drain (source/drain) region at the surface of the substrate; a raised semiconductor layer deposited over the source/drain region to form a raised source/drain region; a via formed in the raised source/drain region to form a hole having substantially vertical sidewalls reaching partly or substantially to the substrate source drain region; and a metal contact filling the raised source/drain region to increase the surface area contact by virtue of the substantially vertical sidewalls of the contact via in the raised source/drain region.

In one embodiment, a method of making reduced resistance contacts in CMOS source/drain regions includes growing an epitaxial source/drain region over a substrate source/drain region; isolating the raised source/drain region from the one or more gate contact regions with an insulating spacer; forming an etch mask layer over the surface of the CMOS device, wherein the mask layer exposes a portion of the raised source/drain region; etching the exposed portion of the raised source/drain region to form a cavity having sidewalls that at least partially extend through the substrate source/drain region; forming a metal contact in the etched portion with extended contact surface with the sidewalls, thereby reducing contact resistance.

In accordance with one embodiment, a method for increasing a contact area to a source/drain region in a CMOS transistor is provided. The transistor comprises a semiconductor source-channel-drain region, and metal contacts provided to the source and/or drain regions. Effective channel length may be increased by forming a raised source/drain using selective epitaxial growth. An epitaxy layer can be formed to a predetermined thickness on a portion of the substrate where source/drain junctions are formed so that the resultant structure is higher than the substrate (i.e., providing a raised source/drain structure above the channel). The raised source/drain structure can effectively increase the effective channel length, resulting in reduced short channel effects. Furthermore, the increased height of the raised source/drain region provides an additional dimension along which metallic contact to the source/drain can be made, thus reducing parasitic contact resistance.

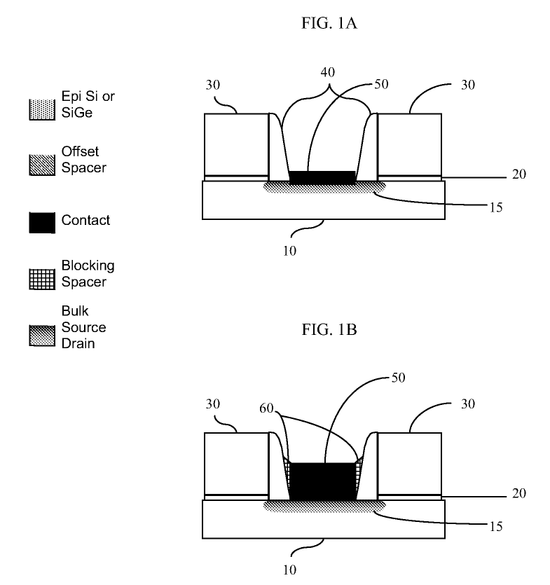

FIG. 1A shows a cross-section of a MOSFET device (which may be either NMOS or PMOS), illustrating the contact area of a source or a drain region. The contact resistance of the device is inversely proportional to the area of the interface between the contact and source or drain regions. As device geometries scale to smaller sizes, this area is reduced, increasing contact resistance and degrading device performance. In some embodiments, the noted problem is often addressed by making deeper source/drain regions and increasing the contact depth which results in increased approximately vertical contact interface area and reduced resistance. Unfortunately however, deeper source/drain regions may degrade short channel effects, with the result that the device operates at an undesirably higher threshold voltage.

Referring to FIG. 1A, a semiconductor substrate 10 in accordance with one embodiment includes a doped source/drain region 15. An insulating layer 20 may be deposited on a portion of substrate 10 over which a first and a second gate electrode contacts 30 are spaced apart from each other. Gate contacts 30 may include a metal fill with a substantially vertical height dimension to reduce gate contact resistance. An insulating spacer 40 may be deposited on an approximately vertical sidewall of each gate electrode and also covering a short portion of source/drain region 15 adjacent to each of the gates 30. A thin metallized source/drain contact layer 50 may be deposited on the remaining exposed portion of source/drain region 15. With scaling reduction in device dimensions, the contact resistance may undesirably increase in some embodiments.

FIG. 1B shows a cross section of a MOSFET (either NMOS or PMOS) device, illustrating a source/drain region having a raised contact. While contact resistance may be reduced for a given device scale, further device scaling to smaller dimensions may continue to degrade interface resistance. The device of FIG. 1B may improve on the device of FIG. 1A by adding a raised source/drain metal contact 50, where an optional additional blocking spacer 60 is first formed by appropriate deposition, masking and etching to control the substantially vertical and lateral dimensions of metal contact 50. While raised source/drain contact 50 may provide reduced resistance for a given device, with scaling reduction in device dimensions, the contact resistance may increase.

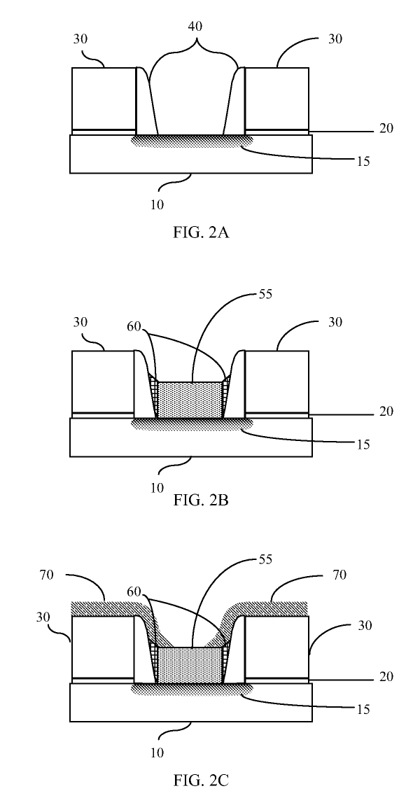

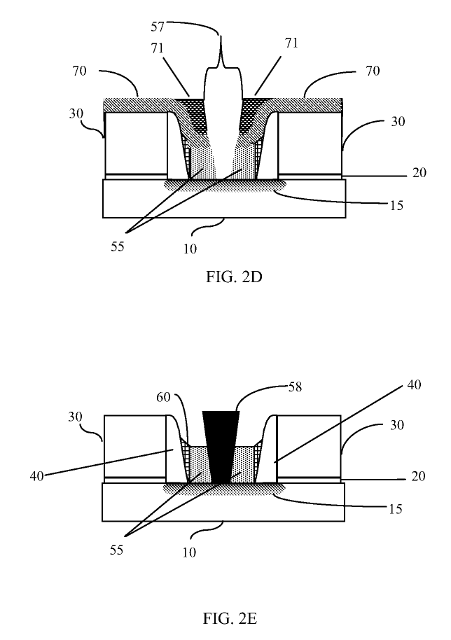

Referring to FIGS. 2A-2E various layers in forming an improved source drain region according to one embodiment is provided. As shown, improved short channel effects may be implemented by raising the source/drain and improving contact resistance by increasing contact area via maximizing approximately vertical and horizontal contacts in the given area. In one embodiment, a MOSFET fabrication process is utilized to form semiconductor layers illustrated in the above-noted figures up to and including the point of spacer formation.

In the following, certain processes and features are discussed in relation to the fabrication process. For brevity, numeral references may not be repeated in all figures for all elements or features of the fabricated device. It is noteworthy, however, that the unnumbered elements and features are not to be deemed excluded from said figures, unless it is explicitly stated as such.

Referring to FIG. 2A, the structural features and fabrication process for the illustrated semiconductor device may be the same or similar to that of the device shown in FIG. 1A. Referring to FIG. 2B, additional semiconductor material may be deposited epitaxially and may be doped appropriately for improved conductivity, forming a raised source/drain region 55 above the original source/drain region 15. For example, where the semiconductor device is silicon, the epitaxial raised source/drain may comprise doped or undoped silicon, SiGe or Ge. Blocking spacer 60 may be disposed filling the area between the approximately vertical sidewalls of the raised source/drain of spacer 40. Examples of commonly used blocking spacer 60 material include, but are not limited to, silicon oxide and silicon nitride. Referring to FIG. 2C, a contact spacer 70 is formed as a protective mask over the structure as shown in FIG. 2B, and a portion is removed to expose a portion of raised source/drain region 55. Contact spacer 70 may comprise one or more of silicon oxide, silicon nitride, or a nitrate etch stop layer (NESL).

A blocking layer 71 (shown in FIG. 2D) may be deposited and etched to form sidewalls to limit and shape formation of a contact 58, to be described later with reference to FIG. 2E. Blocking layer 71 may be formed from one or more layered depositions of a plurality of etch stop and/or blocking layer materials patterned by etchants to achieve a preferred shape affecting formation of contact 58. Blocking layer may comprise one or more of silicon oxide, silicon nitride, or NESL Referring to FIG. 2D, the exposed portion of raised source/drain region 55 may be etched to form a via 57 that penetrates the body of raised source/drain region 55 to source/drain region 15 of substrate 10.

A contact 58 may then be deposited in via 57 to form a contact with the approximately vertical sidewalls of via 57 formed in raised source/drain region 55, and having a further height and shape as determined by blocking layer 71. Contact 58 may be a salicide, a metal, a combination of both, or any other suitable metal, composite or a combination thereof. A suitable metal, if chosen, may be copper, silver, tungsten, a refractory metal such as tantalum or titanium, but the selection is not limited to these, as they are listed as exemplary. In one embodiment the approximately vertical contact interface between metal contact 58 and raised source/drain region 55 allows for added contact area thereby reducing contact resistance. Contact spacer 70 may then be removed by etching or dissolution. The source/drain contact thus formed may improve device performance by reducing contact resistance. However, it will be noted that the contact 58 formed in this manner is narrow, and may rely on the depth of the raised source/drain region for increased contact area.

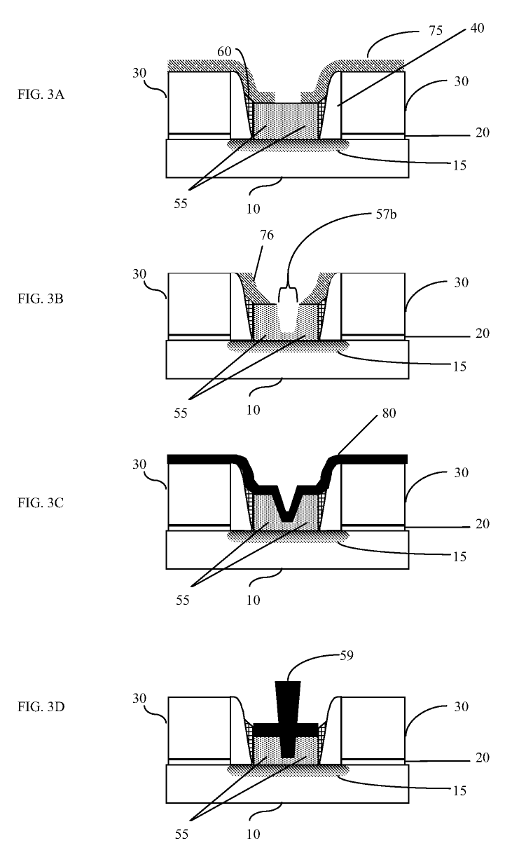

FIGS. 3A-3D illustrate a fabrication process for an improved contact in a non-faceted source/drain region according to another embodiment. In this implementation, the surface area dimensions of the source/drain region may be reduced while taking further advantage of the third dimension (i.e., the height) to increase contact surface area and reduce contact resistance. The fabrication process leading to the structure shown in FIG. 3A may be the same or similar to that shown in FIG. 2A. In certain implementations, an epitaxial growth of semiconductor material above the source/drain region may fully or partially fill the openings above the substrate source-drain regions 15 and between blocking spacers 60.

In one embodiment, the epitaxial source/drain region 55 is grown to a height that is less than the height of the gate contact 30. A uniform blocking layer 75 may be deposited over the device, and will have a somewhat vertical portion blocking layer 76 as a result of source/drain region 55 having the lower height. An anisotropic etch may thus be performed on the blocking layer 75 to remove the substantially horizontal portion of blocking layer material 75 by etching approximately vertically, desirably leaving a portion of the blocking layer material 76 (shown in FIG. 3B) formed somewhat vertically along the blocking spacer 60. An example of such anisotropic etch may be a plasma in which etching action is preferentially vertical, thus having a reduced horizontal (i.e., lateral) etching effect, thereby leaving the substantially vertical portion of blocking layer 76 as a result of the approximately vertical orientation of the wall upon which it was deposited. Depending on implementation, an oxide etch (e.g., a low-density plasma, or CCP-type plasma) or a nitride etch (e.g., a high-density, ECR or ICP-type plasma) may be used.

Referring to FIG. 3B, an isotropic etch (either wet or dry) partially etches away the approximately vertical planar portions of blocking layer 76 while also forming a hole 57b either fully or partially into the exposed portion of raised source/drain 55. Desirably, in one implementation, hole 57b does not go entirely through raised source/drain region 55. Control of the depth of the etch into raised source/drain region 55 may be achieved, for example, by controlling at least one of the etch time, etch concentration parameters, temperature, or a combination of the same. A portion of blocking layer 76 may be left protecting a portion of raised source/drain region 55, blocking spacer 60 and gate insulating spacer 40. Following the formation of hole 57b, an isotropic etch may be used to remove the remaining blocking spacer material 76.

Referring to FIG. 3C, a metal seed layer 80 may be formed for the contact by way of metal deposition. Photoresist and photolithographic patterning to protect the metal layer 80 may be applied desirably directly over the raised source/drain region 55, followed by metal etching to leave the metal seed layer 80 covering only the raised source/drain region 55. The metal contact may be then filled in and built up in a substantially vertical direction by, for example, an electroless plating process, which desirably grows on the metal contact seed layer to later provide a base for growing a metal contact that is self-aligned over the raised source/drain region 55 and has maximum horizontal surface area and enhanced vertical wall contact area.

Referring to FIG. 3D, metal contact 59 may then be deposited by forming blocking and/or etch stop layers substantially as described with respect to FIGS. 2D and 2E.

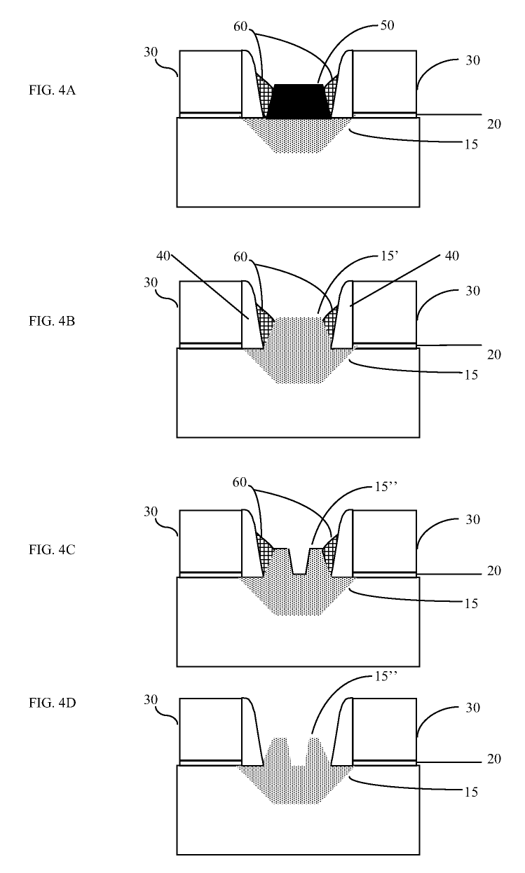

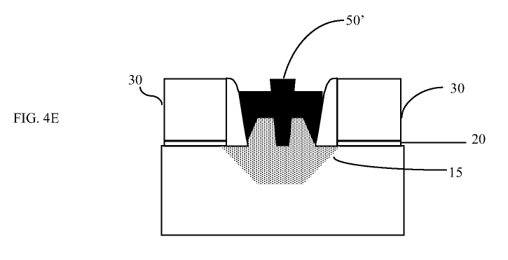

In certain embodiments, the source/drain contact resistance may be further reduced as provided in more detail below. FIGS. 4A-4D illustrate an exemplary fabrication process forming an improved contact in a faceted raised source/drain region according to one embodiment. FIG. 4A may represent a prior art implementation of a metal or silicide contact 50 formed over a source./drain region 15. It should be appreciated that the contact area between contact 50 and source/drain region 15 will decrease as device scaling advances to smaller dimensions.

Referring to FIG. 4B, an epitaxial raised source/drain region 15′ may be grown from source/drain region 15. Since the growth may be single crystal epitaxy, raised

Referring to FIG. 4C, the device surface is masked with a resist such that a central portion of raised source drain region 15′ is exposed to an etchant. As raised source drain region 15′ is epitaxial and highly crystalline in quality, it may be susceptible to highly anisotropic orientationally dependent etching. The exposed surface may therefore etch anisotropically to form a trench to provide the raised source/drain region 15″. In some embodiments, the trench may have faceted sides.

Referring to FIG. 4D, the blocking spacer may be removed by an appropriate etchant, leaving a corrugated top surface of raised source/drain region 15″ fully exposed, for example. With appropriate masking, as shown in FIG. 4E, a metal seed layer may be deposited over raised source/drain region 15″. The seed layer may be formed by deposition of a highly conductive metal, or by silicidation of the raised source/drain region 15″. This may be desirably followed by building up a thick metal contact 50′. The method of forming metal contact 50′ may be, for example, electroless plating, and rely on use of blocking and/or etch stop layers as described earlier. As can be appreciated from FIG. 4E, the contact surface area of metal to raised source/drain region 15″ is greatly increased by creating access to the faceted sidewalls of the epitaxial material, with resulting decrease in contact resistance.

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multi-chip package (such as a ceramic carrier that has either or both surface interconnections of buried interconnections).

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multi-chip package (such as a ceramic carrier that has either or both surface interconnections of buried interconnections).

In any case, the chip is then integrated with other chips, discrete circuit elements, and/or other signal processing devices as part of either (a) an intermediate product, such as a motherboard, or (b) an end product. The end product may be any product that includes integrated circuit chips, ranging from toys and other low-end applications to advanced computer products having a display, a keyboard or other input device, and a central processor.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus comprising:
a semiconductor substrate;
a conductively doped source or drain (source/drain) region at the surface of the substrate;
a raised semiconductor layer deposited over the source/drain region to form a raised source/drain region;
a via formed in the raised source/drain region having substantially vertical sidewalls reaching partly or substantially to the source/drain region; and
a metal contact filling the via.

2. The contact of claim 1, wherein the raised semiconductor layer is an epitaxially grown layer.

3. The contact of claim 1, wherein the MOSFET is NMOS or PMOS.

4. The contact of claim 1, further comprising the metal contact covering the top surface of the raised source/drain region.

5. The contact of claim 1, wherein the hole is etched to form substantially vertical sidewalls in the raised source/drain region for receiving metal for contact.

6. The contact of claim 1, wherein the hole is formed with an isotropic etch to provide substantially non-vertical sidewalls for receiving metal for contact.

7. The contact of claim 1, wherein the raised source/drain region is epitaxial and the via and portions of the sides of the raised source/drain region are anisotropically etched.

8. The method of claim 7, wherein the via and portions of the sides of the raised source/drain region are anisotropically etched along crystallographic plane to form a faceted surface, including portions with a flat top.

9. The contact of claim 7, wherein metal is deposited on the exposed faceted surfaces of the raised source/drain region.

10. The contact of claim 1, wherein raised source/drain region is isolated from electrical contact with one or more gates by blocking spacers.

11. A method comprising:
growing an epitaxial source/drain region over a substrate source/drain region proximate to one or more gate contact regions spaced apart from each other;
isolating the raised source/drain region from the one or more gate contact regions with an insulating spacer;
forming an etch mask layer over the substrate exposes a portion of the raised source/drain region;
etching the exposed portion of the raised source/drain region to form a via having sidewalls at least partially therethrough toward the substrate source/drain region; and
depositing a metal in the via to form a contact.

12. The method of claim 11, wherein the CMOS device is NMOS or PMOS.

13. The method of claim 11, further comprising etching the exposed portion of the raised source/drain region with an anisotropic etchant to form substantially vertical sidewalls in the raised source/drain region.

14. The method of claim 11, further comprising etching the exposed portion of the raised source/drain region with an isotropic etchant to form substantially non-sidewalls in the raised source/drain region.

15. The method of claim 11, further comprising etching portions of the raised source/drain region at the exposed portions along crystallographic planes to form a faceted surface.

16. The method of claim 11, further comprising depositing the metal by a metal seed layer deposited through an exposed portion of a mask.

17. The method of claim 16 further comprising removing the mask after the formation of the metal seed layer.

18. The method of claim 17, further comprising depositing additional metal using electroless deposition, wherein the deposition at least fills the via etched in the raised source/drain region.

19. The method of claim 16, further comprising forming the metal by a metal seed layer deposited on the faceted surface of the raised source/drain region through an exposed portion of a mask, wherein the mask is removed after the formation of the metal seed layer.

20. The method of claim 19, further comprising depositing additional metal using electroless deposition, wherein the metal deposition at least fills the via etched in the raised source/drain region, the top and the etch exposed faceted surfaces.
